(19) United States
(12) Patent Application Publication
(10) Pub. No.: US 2008/0018841 A1
(43) Pub. Date: Jan. 24, 2008

(54) Methods and apparatus for forming LCD alignment films

(75) Inventors: Soon-joon Rho, Suwon-si (KR); Jin-soo Jung, Goyang-si (KR); Baek-kyun Jeon, Yongin-si (KR); Hee-keun Lee, Suwon-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/818,875

(22) Filed: Jun. 15, 2007

(30) Foreign Application Priority Data
Jul. 24, 2006 (KR) 10-2006-0069260
Dec. 19, 2006 (KR) 10-2006-0130209

(51) Int. Cl. G02F 1/1337; B29D 11/00; H01L 21/3065

(52) U.S. Cl. 349/124; 204/230.2; 216/14; 216/24

(57) ABSTRACT

A method for forming alignment films in LCDs includes forming a conductive film on an LCD substrate, forming an inorganic alignment film on the conductive film, and etching the alignment film with an etching apparatus that includes a nozzle that sprays a plasma at atmospheric pressure onto a surface of the alignment film without using a mask pattern so as to form an etched region in the alignment film that exposes a portion of the underlying conductive film therethrough. The novel method enables LCD alignment films having sharp thickness profiles to be patterned easily and accurately, reduces the time required to manufacture LCDs, and minimizes the number of devices required to manufacture the LCDs.

### RELATED APPLICATIONS

This application claims priority of Korean Patent Application Nos. 10-2006-0069260 and 10-2006-0130209, filed Jul. 24, 2006 and Dec. 19, 2006, respectively, the entire disclosures of which are incorporated herein by reference.

### BACKGROUND

This invention relates to methods and apparatus for forming alignment films in liquid crystal displays (LCDs) and to LCDs manufactured using the method, and more particularly, to such methods and apparatus that enable LCD alignment films to be patterned easily, accurately and with desirably sharp sidewall profiles.

To display images, LCDs generally employ a technique for controllably aligning the molecules of a layer of a liquid crystal material of the display in selected directions. According to one such early liquid crystal molecule alignment technique, an organic thin film made of polyimide or another polymer is printed on a substrate of the LCD, and grooves are then formed in the film with a roller on which a cloth (e.g., velvet) is wound, to thereby form an alignment film.

When the above method is used to form an alignment film on an LCD substrate, it is necessary to employ a printing technique that can accurately control both the position at which the alignment film is formed in an active area of the substrate and the uniformity of the alignment film formed thereon. However, as the size of “mother glasses,” i.e., the large substrates from which several individual LCD substrates are subsequently cut, increase, this requirement becomes more difficult to meet. In particular, in cases wherein an organic alignment film made of polyimide is exposed to strong ultraviolet (UV) light for a long period of time in order to cure it, the film may be degraded, thereby lowering the liquid crystal alignment property of the alignment film.

In view of the above problem, a new type of alignment film made of an inorganic material has recently been proposed. An LCD using such an alignment film typically comprises a color filter substrate and a thin film transistor (TFT) substrate. A common electrode formed over the entire surface of the color filter substrate is electrically connected to a common voltage terminal of the TFT substrate via a transfer electrode. Alignment films of an inorganic material are respectively formed on the common voltage terminal of the TFT substrate and the common electrode of the color filter substrate. Thus, in order to electrically connect the common voltage terminal of the TFT substrate and the common electrode of the color filter substrate via the transfer electrode, it is necessary to perform a patterning process on the inorganic alignment film to partially remove the film at the respective locations of the common voltage terminal and the common electrode.

Conventionally, a patterning process that uses a photoresist film is used to pattern such inorganic alignment films. According to the conventional patterning process, a photoresist film is coated on the alignment film, etched using photolithography, and developed to form a photoresist film pattern. The alignment film is then etched using the photoresist film pattern as an etching mask.

Thus, in accordance with the above-described conventional LCD alignment film forming method, an additional photolithography process is required to pattern the alignment film. This additional process not only increases the processing time necessary to form the alignment film, but also requires many additional processing devices, such as masks, exposure machines, etching machines, and the like, thereby increasing manufacturing costs.

### BRIEF SUMMARY

In accordance with the exemplary embodiments thereof described herein, the present invention provides methods and apparatus for forming LCD alignment films that enable the alignment film to be patterned easily, accurately, with desirably sharp sidewalls, and without using a mask, as well as LCDs manufactured using the novel methods and apparatus.

In accordance with one particular exemplary embodiment, a method for forming an LCD alignment film includes forming a conductive film on an LCD substrate, forming an inorganic alignment film on the conductive film, and etching the inorganic alignment film using an alignment film etching apparatus, including a nozzle spraying a plasma at atmospheric pressure, and without using a mask pattern, to form an etched region in the alignment film that exposes a portion of the underlying conductive film therethrough.

In accordance with another exemplary embodiment, an LCD includes a substrate comprising an active area and a periphery area, a conductive film disposed on the substrate, and an inorganic alignment film disposed on the conductive film, the alignment film having an etched region positioned between the active area and the periphery area and through which the conductive film is exposed. In this embodiment, the sidewall profile of the inorganic alignment film of the active area adjacent to the etched region is advantageously sharper than the sidewall profile of the inorganic alignment film of the periphery area adjacent to the etched region.

In accordance with still another exemplary embodiment, an alignment layer etching apparatus includes a power electrode to which a high voltage is applied, a ground electrode, a nozzle which is interposed between the power electrode and the ground electrode, and which is operable to generate an atmospheric pressure plasma for etching an LCD alignment film disposed on a substrate, and a barrier formed at an end of the nozzle to surround the atmospheric pressure plasma.

A better understanding of the above and many other features and advantages of the novel methods and apparatus for forming LCD alignment films of the invention, as well as LCDs manufactured using such methods and apparatus, may be obtained from a consideration of the detailed description of some exemplary embodiments thereof below, particularly if such consideration is made in conjunction with the appended drawings, wherein like reference numerals are used to identify like elements illustrated in one or more of the figures thereof.

### BRIEF DESCRIPTION OF THE DRAWINGS

FIG. 1 is a schematic partial cross-sectional elevation view of an exemplary embodiment of an alignment film etching apparatus being used in an exemplary embodiment of a method for forming an LCD alignment film in accordance with the present invention;

FIG. 2 is an enlarged schematic partial cross-sectional elevation view of the alignment film etching apparatus of FIG. 1, illustrating a nozzle of the apparatus and an adjacent LCD alignment film being etched thereby;

FIG. 3 is an enlarged schematic partial cross-sectional view of the exemplary alignment film etching apparatus being used in another exemplary embodiment of a method for forming an LCD alignment film in accordance with the present invention;

FIG. 4 is a graphical representation of the cross-sectional profile of an opening in an alignment film patterned using the exemplary alignment film etching apparatus and method of FIG. 3;

FIG. 5 is a process flow diagram of an exemplary embodiment of a method for manufacturing an LCD using the exemplary alignment film forming methods and apparatus of the present invention;

FIG. 6 is a schematic top plan view of an LCD thin film transistor (TFT) substrate having an alignment film formed thereon using the exemplary alignment film forming methods and apparatus of the present invention;

FIG. 7 is a partial schematic cross-sectional view of an exemplary LCD, including a TFT substrate and a color filter substrate, each including an alignment film formed thereon using the exemplary methods and apparatus of the present invention;

FIG. 8 is a schematic partial cross-sectional elevation view of an exemplary embodiment of an alignment film etching apparatus being used in an exemplary embodiment of a method for forming an LCD alignment film in accordance with the present invention; and,

FIG. 9 is an enlarged cross-section view of the alignment film etching apparatus of FIG. 8 illustrating a process in which a barrier of the apparatus is used to limit an area in which atmospheric pressure plasma is generated.

### DETAILED DESCRIPTION

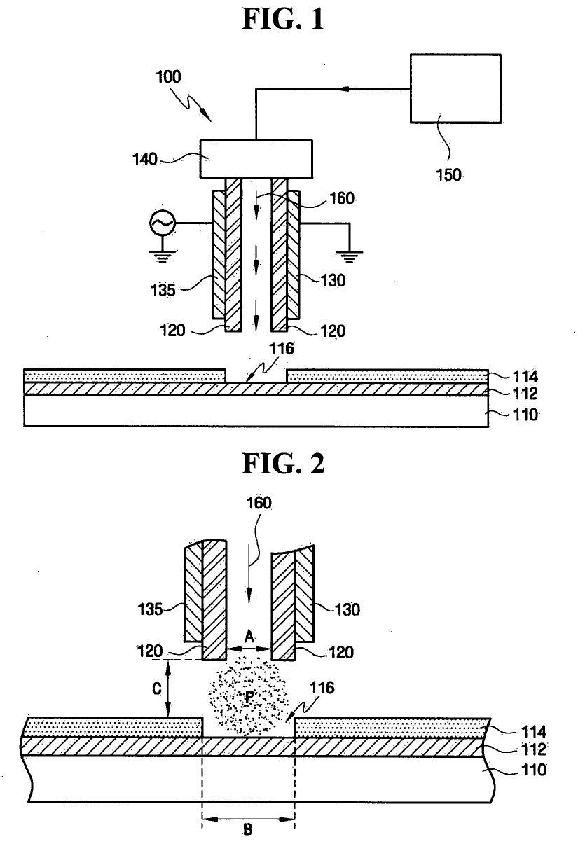

FIG. 1 is a schematic partial cross-sectional elevation view of an exemplary embodiment of an alignment film etching apparatus 100 being used in an exemplary embodiment of a method for forming an LCD alignment film in accordance with the present invention. As illustrated in FIG. 1, the apparatus 100 includes a power electrode 135 to which a high voltage is applied, a ground electrode 130, and a dielectric annular nozzle 120 interposed between the power electrode 135 and the ground electrode 130, and is operable to generate an atmospheric pressure plasma for selectably etching an LCD alignment film 114 disposed below the apparatus in the manner described below. That is, the alignment film etching apparatus 100 of the present invention is adapted to pattern the alignment film 114 using a plasma at atmospheric pressure and without using a mask pattern. The alignment film etching apparatus 100 can thus generate a plasma at atmospheric pressure without using a vacuum chamber and a vacuum pump.

In FIG. 1, the power electrode 135 and the ground electrode 130 are disposed opposite to each other and generally perpendicular to a substrate 110 that is to be processed by the apparatus. The nozzle 120 is disposed between the power electrode 135 and the ground electrode 130. The annular nozzle 120 is made of a dielectric material, and thus, electrically insulates the power electrode 135 and the ground electrode 130 from each other. The nozzle 120 is used as a supply channel of a reaction gas 160 for generating an atmospheric pressure plasma.

As illustrated in FIG. 1, a Mass Flow Controller (MFC) 140 is disposed at an upper end of the nozzle 120 to control the rate of flow of the reaction gas 160 into and through the nozzle 120. A reaction gas supplier 150 is coupled to an inlet of the MFC 140 for supplying the reaction gas 160 to the nozzle 120.

As the reaction gas 160 from the MFC 140 flows downward through the nozzle 120, a high voltage is applied between the power electrode 135 and the ground electrode 130, thereby generating a glow discharge, which energizes the flowing reaction gas 160 into a plasma state. As used herein, “plasma state” refers to a net neutral state of ions or electrons generated when energy is applied to neutral atoms or molecules. The energy of a plasma state is much higher than that of a gaseous state, and matter that is in a plasma state contains a large amount of reactive radicals, which enable the surface of a subject to be etched thereby. As the reaction gas 160 passes further through the nozzle 120, the density of the plasma increases. As the reaction gas 160 moves away from the lower ends of the power electrode 135 and the ground electrode 130, the density of the plasma decreases, thereby decreasing the amount of radicals present.

The substrate 110 disposed below the nozzle 120A includes a conductive film 112 and the alignment film 114, which are sequentially formed thereon. The substrate 110 may be a Thin Film Transistor (TFT) substrate or a color filter substrate of an LCD. The alignment film 114 may be an inorganic alignment film, and the conductive film 112 may be a common voltage terminal of the TFT substrate or a common electrode of the color filter substrate.

The TFT substrate includes a plurality of gate lines, data lines, and pixel electrodes. The gate lines extend in a row direction and are responsible for the transmission of gate signals, and the data lines extend in a column direction and are responsible for the transmission of data signals. The pixel electrodes are connected to switching devices connected to the gate lines and the data lines.

The color filter substrate is disposed above the TFT substrate. The color filter substrate includes red, green, and blue color filters corresponding to respective ones of the pixel electrodes so that a respective color can be displayed in each pixel. A common electrode made of a transparent conductive material, such as Indium Tin Oxide (ITO) or Indium Zinc Oxide (IZO), is disposed over the color filters.

An LCD typically includes a TFT substrate and a color filter substrate as described above, as well as a layer of a liquid crystal material having dielectric anisotropy interposed between the TFT and the color filter substrates. The liquid crystal layer functions to adjust the transmittance of light passing through the liquid crystal layer by changing the arrangement of liquid crystal molecules, which is effected by applying a voltage thereto from an external source. An alignment film for achieving a desired orientation of the molecules of the liquid crystal layer is disposed on each of the TFT and the color filter substrates.

A common voltage is applied to a common electrode of the color filter substrate via a common voltage terminal of the TFT substrate. To apply the common voltage, a transfer electrode is formed that connects the common electrode of the color filter substrate and the common voltage terminal of the TFT substrate.

However, since an alignment film is present between the common voltage terminal of the TFT substrate and the transfer electrode, it is necessary to etch away a selected portion of the alignment film formed on the common voltage terminal so that the common voltage terminal can contact the transfer electrode. Also, since an alignment film is present between the common electrode of the color filter substrate and the transfer electrode, it is likewise necessary to etch away a selected portion of the alignment film formed on the common electrode so that the common electrode can contact the transfer electrode.

When the alignment film etching apparatus 100 is in operation, atmospheric pressure plasma generated from the reaction gas 160 is sprayed from the nozzle 120 onto the upper surface of the alignment film 114 disposed below the nozzle 120 so as to selectably etch the surface of the alignment film 114, thereby forming an etched region 116 through which a selected portion of the underlying conductive film 112 is exposed. The conductive film 112 may be a transparent conductive film made of, e.g., ITO, IZO, or the like, or alternatively, a metal wire.

When the substrate 110 is a color filter substrate, the conductive film 112 may be a common electrode formed over the color filters. When the substrate 110 is a TFT substrate, the conductive film 112 may be a common voltage terminal formed on the TFT substrate to apply a common voltage to a common electrode.

The alignment film 114 may comprise an inorganic alignment film material. The alignment film 114 may be made of an inorganic material including silicon, e.g., amorphous hydrogenated silicon, silicon carbide (SiC), silicon oxide (SiOx), silicon nitride (Si₃N₄), or like materials. Such an inorganic alignment film can be formed by a so-called “thin film deposition process” using, e.g., sputtering, chemical vapor deposition, or the like, which is more advantageous in terms of productivity than a conventional printing method using a resin printing plate. Preferably, the alignment film 114 is made of silicon oxide (SiOx).

The alignment film 114 is easily etched by atmospheric pressure plasma generated from the reaction gas 160, whereas, the conductive film 112 disposed below the alignment film 114 is not easily etched by the atmospheric pressure plasma. That is, if the reaction gas 160 is selected such that the etching selectivity of the alignment film 114 with respect to the conductive film 112 is high, no etching damage will occur to the conductive film 112 disposed below the alignment film 114 during the etching of the alignment film 114.

In one exemplary embodiment, the reaction gas 160 may comprise a SF₆-containing gas. For example, a mixture of gaseous N₂ and SF₆ in a ratio of from about 5:1 to about 50:1 may be used.

The plasma discharged from the lower end of the nozzle 120 of the alignment film etching apparatus 100 tends to disperse in all directions due to the low directionality of the nozzle. Thus, in order to etch a desired portion (referred to herein as an etched region 116) of the alignment film 114 using atmospheric pressure plasma without using a mask, it is necessary to control both the dimension of the nozzle 120 of the alignment film etching apparatus 100, and the distance between the nozzle 120 and the alignment film 114, and accordingly, these two dimensional parameters are deemed to be of primary importance, for the reasons discussed below.

An exemplary embodiment of a method for etching an LCD alignment film 114 so that the etched region 116 has relatively vertical sidewalls, i.e., a keen or sharp sidewall profile in the direction of the thickness of the film, is described below with reference to FIG. 2, which is an enlarged schematic partial cross-sectional elevation view of the nozzle 120 of the alignment film etching apparatus 100 of FIG. 1, illustrating the dimension A of the nozzle and the distance C between the nozzle 120 of the apparatus and the alignment film 114 described above.

Referring to FIG. 2, as the distance C between the nozzle 120 and the alignment film 114 increases, the atmospheric pressure plasma P tends to disperse outwardly from the nozzle in all directions. Thus, in order for an etched region 116 to have a desirably vertical, or sharp, sidewall profile, i.e., in the direction of the film's thickness, and more specifically, in order for the alignment film 114 adjacent to the etched region 116 to have a sharp sidewall profile, the diameter B of the circular etched region 116 should be controlled to be between about 1-2.5 times the inner diameter A of the annular nozzle 120. For example, when the diameter A of the nozzle 120 is about 1 mm, the diameter B of an etched region 116 having a relatively vertical or sharp sidewall profile will be between about 1 to about 2.5 mm. If the diameter B of the etched region 116 exceeds about 2.5 times the diameter A of the nozzle 120, then the plasma P will disperse excessively in all directions, and as a result, the alignment film 114 adjacent to the etched region 116 will have a relatively broad or sloping sidewall profile, which lowers the alignment property of the alignment film in an active area of the LCD.

In order to maintain the ratio of the diameter B of the etched region 116 to the diameter A of the nozzle 120 to between about 1-2.5, the distance C between the nozzle 120 and the alignment film 114 should be controlled to be between about 0.25-0.75 mm. If the distance C between the nozzle 120 and the alignment film 114 is less than 0.25 mm, arcing may occur between the nozzle 120 and the alignment film 114. On the other hand, if the distance C between the nozzle 120 and the alignment film 114 is greater than about 0.75 mm, the etched region 116 will have an excessively broad sidewall profile.

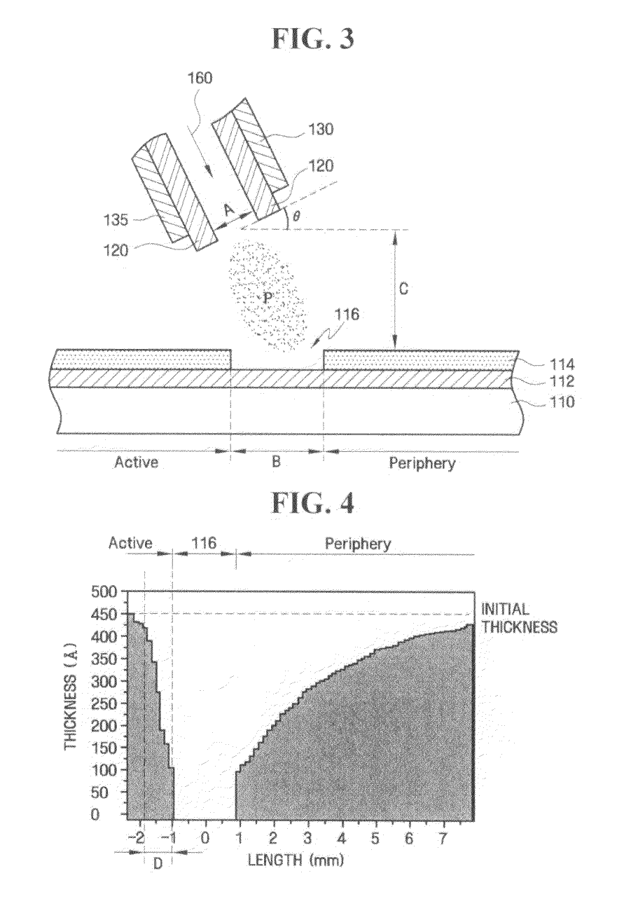

Another exemplary embodiment of a method for forming an alignment film of a LCD in accordance with the present invention is described in detail below with reference to FIGS. 3 and 4. FIG. 3 is an schematic partial cross-sectional view of an alignment film etching apparatus used in the second exemplary method, and FIG. 4 is a graphical representation of the cross-sectional sidewall profile of an alignment film patterned using the alignment film etching apparatus and exemplary method of FIG. 3. A detailed description of those components having the same function and identified by the same reference numerals as those described above and illustrated in FIGS. 1 and 2 is omitted for brevity.

Referring to FIGS. 3 and 4, a nozzle 120 is inclined at a tilt angle θ with respect to the upper surface of a substrate 110 so that plasma P from the nozzle 120 is sprayed obliquely onto the surface of an alignment film 114 disposed on the substrate. That is, the nozzle 120 is inclined at a tilt angle θ relative to the substrate such that it points more directly toward a “periphery” area of the substrate, and away from an “active” area of the substrate, as illustrated in the figures. Since the nozzle 120 faces more directly toward the periphery area, the plasma P sprayed from the nozzle 120 does not cause damage to the alignment film 114 disposed in the active area of the substrate. The active area of the substrate is an area in which pixels of a TFT substrate or a color filter substrate are positioned, and the periphery area is an area of the substrates that is cut away and discarded after the TFT and the color filter substrates are assembled together. Thus, even though the plasma P from the nozzle 120 disperses from the nozzle in all directions to partially etch the alignment film 114 in the periphery area, the alignment characteristics of the alignment film 114 in that area are irrelevant, since the periphery area is cut away and disposed of in a subsequent process.

That is, it is preferable that the alignment film 114 in the active area adjacent to an etched region 116 has a relatively sharp sidewall profile, and is acceptable that the alignment film 114 in the periphery area adjacent to the etched region 116 has a broad profile, since the latter region is subsequently discarded. To achieve this desirable end, the tilt angle θ of the nozzle 120 with respect to the upper surface of the substrate 110 should be controlled to be between about 1-45 degrees, and more preferably, between about 5-25 degrees. If the tilt angle θ of the nozzle 120 exceeds about 45 degrees, a damage region D of the alignment film 114 in the active area, as illustrated in FIG. 4, may be enlarged, thereby undesirably lowering the alignment property of the alignment film in the active area.

Although the nozzle 120 is inclined at a selected angle relative to the substrate 110, the distance C between the nozzle 120 and the alignment film 114 should preferably still be controlled to be about 5 mm or less. Here, the distance C between the nozzle 120 and the alignment film 114 refers to the distance between the alignment film 114 and the center of the lower end of the annular nozzle 120. In this case, if the distance C between the nozzle 120 and the alignment film 114 exceeds about 5 mm, the plasma P flowing from the nozzle may disperse excessively and result in the alignment film 114 having an undesirably broad or sloping sidewall profile, such as that illustrated in FIG. 4 at the periphery area of the substrate.

As described above, the diameter B of the etched region 116 should be controlled to be between about 1-2.5 times the diameter A of the nozzle 120. For example, when the diameter A of the nozzle 120 is about 1 mm, the diameter B of the etched region 116 will be about 1-2.5 mm. If the diameter B of the etched region 116 exceeds 2.5 times the diameter A of the nozzle 120, the plasma P may disperse excessively from the nozzle, resulting in the alignment film 114 in the active area, as well that in the periphery area, being etched with an undesirably broad profile. When the ratio of the diameter B of the etched region 116 to the diameter A of the nozzle 120 is maintained at about 1-2.5, as illustrated in FIG. 4, the damaged region D of the alignment film 114 in the active area can be maintained to about 2 mm or less, and more preferably, to about 1 mm or less.

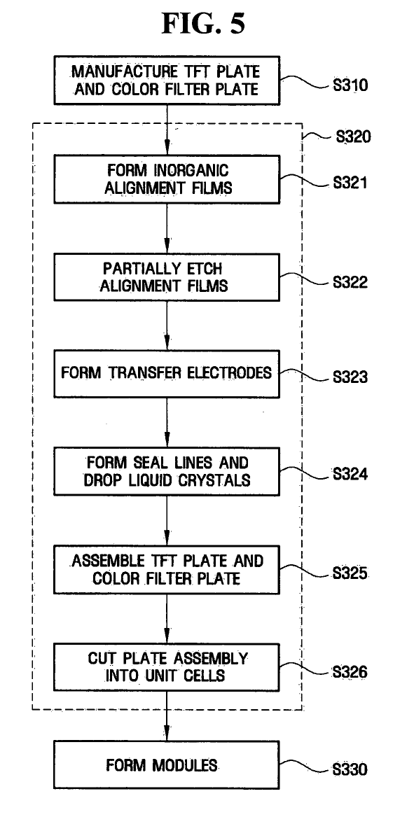

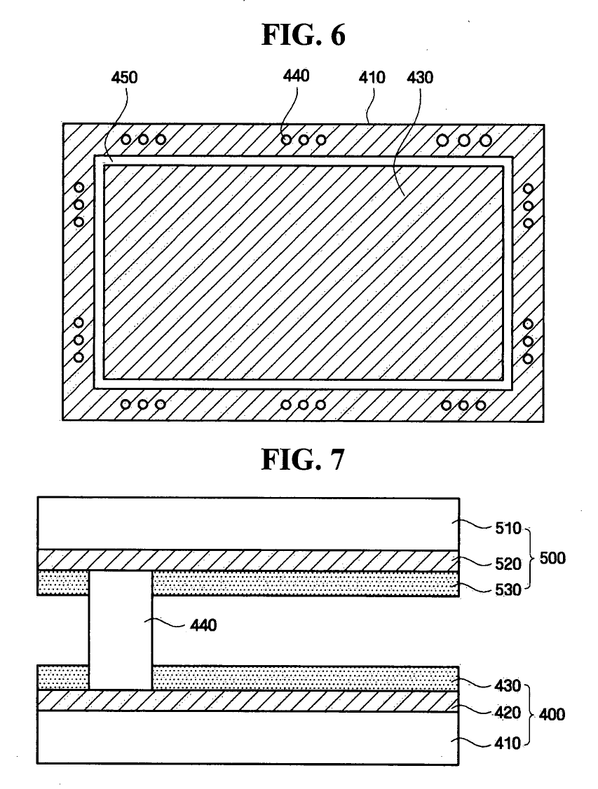

An exemplary embodiment of a method for manufacturing a TFT substrate and a color filter substrate of an LCD, each having an alignment film formed thereon using the above-described alignment film etching apparatus and methods is described below with reference to FIGS. 5 through 7. FIG. 5 is a process flow diagram of the LCD manufacturing method, FIG. 6 is a schematic top plan view of an LCD thin film transistor (TFT) substrate made using the method, and FIG. 7 is a schematic partial cross-sectional view of an LCD, including the TFT substrate of FIG. 6 and a color filter substrate, each having an alignment film formed thereon using the alignment film forming methods of the present invention, after being assembled together.

Referring to FIG. 5, a method for manufacturing an LCD in accordance with the present invention includes a TFT substrate manufacturing process (S310), a color filter substrate manufacturing process (S310), a liquid crystal cell process (S320), and a module process (S330).

In the particular exemplary embodiment of FIG. 5, the TFT substrate manufacturing process (S310) is a process in which a TFT array is formed on a large-sized “mother glass” substrate, and the color filter substrate manufacturing process (S310) is a process in which a common electrode is formed on another large-sized mother glass substrate.

A TFT substrate and a color filter substrate respectively prepared by the TFT substrate manufacturing process (S310) and the color filter substrate manufacturing process (S310) are conjointly subjected to the liquid crystal cell process (S320). The liquid crystal cell process (S320) includes forming alignment films and seal lines on respective ones of the two substrates to define a plurality of unit liquid crystal cells, dripping a liquid crystal material into the unit liquid crystal cells, assembling the two substrates together, and cutting the resultant substrate assembly into individual unit liquid crystal cells using one of various possible cutting tools to yield a plurality of individual LCD panels.

After the liquid crystal cell process (S320), the module process (S330) is performed. In the module process (S330), driving circuits for supplying electrical signals to the liquid crystal cells are attached to the LCD panels.

Following is a more detailed description of the process flow of the liquid crystal cell process (S320) of FIG. 5. As illustrated in FIG. 5, the liquid crystal cell process (S320) includes forming an inorganic alignment film (S321), partially etching the alignment films (S322), forming transfer electrodes (S323), forming seal lines and dropping liquid crystals (S324), assembling (S325), and cutting (S326).

In the forming of the inorganic alignment films (S321), alignment films are respectively formed on the pixel electrodes of a TFT substrate and on the common electrode of a color filter substrate. The alignment films are formed at selected thicknesses over the entire surface of each of the TFT and color filter substrates. As a result of the presence of these alignment films on the two substrates, the molecules of the layer of liquid crystal material disposed between the two substrates are uniformly oriented, thereby ensuring uniform display characteristics over the entire screen area of the display.

The alignment films must have good adhesion property for adhering to a surface made of an electrode material (e.g., ITO), and a film uniformity of 1,000 Å or less at temperatures of 200° C. or less. Also, the alignment films must have sufficient chemical stability so as not to react with the liquid crystal material, must not function as electrical charge trapping media, and must have sufficiently high resistivity so as not to affect the operation of the liquid crystals. In addition, the physical properties of the alignment films must not be degraded when exposed to strong UV light for long periods of time. In view of these required characteristics, the alignment films may be inorganic alignment films. The alignment films are preferably made of amorphous hydrogenated silicon, silicon carbide (SiC), silicon oxide (SiOx), silicon nitride (Si₃N₄), or the like. The alignment films are more preferably made of silicon oxide (SiOx). Alignment films made of silicon oxide may be formed using sputtering or chemical vapor deposition techniques.

Depending on the process conditions, the respective surface of the alignment films can also be aligned using an additional ion-beam or an atomic-beam process.

After the alignment film formation (S321) is completed, the alignment films of the TFT substrate and the color filter substrate corresponding to transfer electrodes are etched to expose the underlying conductive films (S322). To achieve this, the alignment films are patterned using atmospheric pressure plasma generated by an alignment film etching apparatus of the type illustrated in FIGS. 1 through 3. Referring to FIGS. 6 and 7, when the alignment films 430 and 530 respectively formed on a TFT substrate 400 and a color filter substrate 500 are partially etched, the conductive films respectively disposed below the alignment films 430 and 530, e.g., a common voltage terminal 420 of the TFT substrate 400 and a common electrode 520 of the color filter substrate 500, respectively, are exposed through the etched regions of the respective alignment films. In FIGS. 6 and 7, reference numeral 440 indicates a transfer electrode, and reference numerals 410 and 510 refer to respective ones of the two transparent substrates.

Next, a transfer electrode 440 is formed on the exposed portions of the conductive films (S323). Referring again to FIGS. 6 and 7, a common voltage is applied to the common electrode 520 of the color filter substrate 500 via the TFT substrate 400. To achieve this, the common voltage terminal 420 is formed on the TFT substrate 400. In order to connect the common electrode 520 of the color filter substrate 500 and the common voltage terminal 420 of the TFT substrate 400, the transfer electrode 440, which connects the TFT substrate 400 and the color filter substrate 500, is provided, and may be formed on either the TFT substrate 400 or the color filter substrate 500. In the following description, the transfer electrode is assumed to be formed on the TFT substrate.

Next, a seal line is formed along inside edges of the TFT substrate relative to the transfer electrode to firmly attach the TFT substrate and the color filter substrate together and to define a space, or cell gap, between the two substrates for receiving the liquid crystal material (S324). Referring again to FIGS. 6 and 7, the alignment film 430 is formed on the transparent substrate 410, and a seal line 450 is formed along edges of a display area of the TFT substrate 400. As illustrated in FIG. 6, the transfer electrode 440 is disposed in a periphery area outside of the seal line 450.

In the exemplary embodiment illustrated, the seal line 450 may comprise a mixture of a sealant, i.e., an adhesive used for attaching the TFT and color filter substrates to each other, and a plurality of rigid spacers for spacing the two substrates apart by a selected distance so as to define a uniform liquid crystal receiving space, or cell, between the two substrates. In order to maintain a uniform cell gap between the TFT substrate and the color filter substrate, the spacers are disposed not only in the seal line, but also in active areas of the LCD panels.

Next, a liquid containing liquid crystals is dripped onto the color filter substrate (S324) so as to form a uniform layer of the liquid crystal material between the two substrates. Additionally, it should be understood that, while the exemplary embodiment has been described in terms of a liquid crystal dripping technique, the present invention is not limited thereto, and the liquid crystal material may also be injected between the TFT and color filter substrates using a vacuum pressure injection technique.

Next, the TFT substrate with the seal line and the color filter substrate with the liquid crystals are aligned and mated with each other and treated with UV light or heat to cure the seal line so as to fix and seal the TFT substrate and the color filter substrate (S325) to each other. An allowance error for alignment of the two substrates is determined by a design margin of the two substrates. Referring to FIG. 7, the common voltage terminal 420 exposed by the patterned alignment film 430 on the TFT substrate 400 and the common electrode 520 exposed by the patterned alignment film 530 on the color filter substrate 500 are electrically connected through the transfer electrode 440, as described above.

Next, the resultant mother glass substrate assembly is cut into individual LCD cells to produce individual LCD panels (S326). To achieve this, a diamond wheel or the like may be used.

Next, an edge-polishing process may be also be performed on the substrates. In the edge-polishing process, side and edge portions of the TFT and color filter substrates are polished using, e.g., a diamond polishing stone rotating at a high speed.

Then, polarization substrates are respectively attached to an exterior surface of each of the two LCD substrates. The thus-completed LCD panels are subjected to an inspection process for inspecting the electro-optical characteristics and image quality of the panels.

The thus-completed LCD panels are then subjected to the module process (S330). The module process (S330) includes mounting driving integrated circuits (ICs) on the LCD panels, attaching Printed Circuit Boards (PCBs) to the LCD panels, and assembling the LCD panels with backlight units using mold frames, chasses, and other mechanical and structural elements.

For example, the driving ICs can be mounted on the LCD panels using Tape Automated Bonding (TAB) technology, Chip On Board (COB) technology, or Chip On Glass (COG) technology. The PCBs include multi-layered circuit devices and are electrically connected to the driving ICs via Flexible Printed Circuits (FPCs), or the like, to constitute the driving circuit units of the LCDs. The PCBs are formed using Surface Mount Technology (SMT), or the like, and then attached to the LCD panels. The LCD panels with the driving ICs and the PCBs are then referred to as “LCD panel assemblies.”

The individual LCD panel assemblies, together with their respective, separately formed backlight units, are then installed in respective mold frames and chasses to complete the LCDs.

In accordance with the exemplary embodiments illustrated and described herein, an alignment film is patterned to expose a common voltage terminal of a TFT substrate and a common electrode of a color filter substrate contacting a transfer electrode. However, it should be understood that the present invention is not limited to the particular embodiments illustrated and described. The present invention's method for patterning an alignment film can also be applied to any process for exposing a thin film disposed below an alignment film. For example, the alignment film patterning process of the present invention can also be applied to a process for exposing the ends of gate lines or data lines disposed below an alignment film. Since the ends of the gate lines or data lines must be connected to driving ICs, it is necessary to partially etch the alignment film in areas above the ends of the gate lines or the data lines, and the present invention provides an easy, efficient and accurate method for doing this.

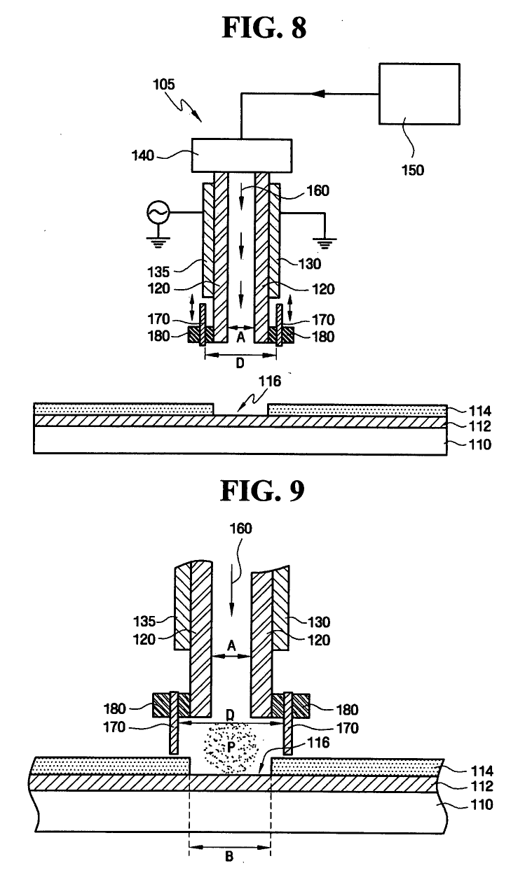

Hereinafter, an alignment film etching apparatus according to still another exemplary embodiment of the present invention is described in detail with reference to FIGS. 8 and 9, wherein FIG. 8 is a partial schematic cross-sectional elevation view of the exemplary alignment film etching apparatus 105. In the following description, a detailed description of those components having the same function and identified by the same reference numerals as those described above and illustrated in FIGS. 1 and 2 is omitted for brevity.

Referring to FIG. 8, the alignment film etching apparatus 105 includes a power supply electrode 135 to which a high voltage is applied, a ground electrode 130 which is grounded, and a dielectric nozzle 120 which is interposed between the power supply electrode 135 and the ground electrode 130, and within which an atmospheric pressure plasma is formed. The atmospheric pressure plasma is used to selectively etch an alignment film 114. The alignment film etching apparatus 105 patterns the alignment film 114 using the atmospheric pressure plasma without the need to use a mask pattern. The alignment film etching apparatus 105 can thus generate a plasma at atmospheric pressure without using a vacuum chamber and a vacuum pump.

A barrier 170 for improving the straightness of the flow of atmospheric pressure plasma is formed at a lower end of the dielectric nozzle 120. In other words, the barrier 170 extends from the lower end of the dielectric nozzle 120 toward a substrate 110 in a shape of, for example, an annulus. Since the barrier 170 serves to prevent the plasma discharged from the nozzle 120 from dispersing outwardly in all directions from the nozzle 120, the inner diameter D of the barrier 170 is preferably larger than the inner diameter A of the nozzle 120. The barrier 170 may be made of a non-metallic material that does not react with the plasma, for example, a dielectric material or a polymeric material. In order to prevent the barrier 170 from causing scratches to the substrate 110, the barrier 170 is preferably made of a polymeric material, for example, PTFE (Polytetrafluoroethylene), PEEK (Polyether ether ketone), or the like.

The barrier 170 is fixed to the lower end of the nozzle 120 by a buffer driver 180, and the buffer driver 180 is operative to adjustably move the barrier 170 up and down relative to the lower end of the nozzle 120.

As discussed above, the plasma discharged from the alignment film etching apparatus 105 tends to disperse in all directions due to low directionality. Thus, when the barrier 170 at the end of the nozzle 120 of the alignment film etching apparatus 105 is used with the apparatus, a desired portion (referred to herein as an etched region 116) of the alignment film 114 can be etched by an atmospheric pressure plasma without using a mask.

The operation of the barrier 170 to achieve directionality of the plasma is described below with reference to FIGS. 8 and 9, wherein FIG. 9 is an enlarged cross-section view of the alignment film etching apparatus of FIG. 8 illustrating a process in which the barrier 170 is used to limit the area in which atmospheric pressure plasma is generated.

When the substrate 110 has not yet been loaded into the lower portion of the alignment film etching apparatus 105, the buffer driver 180 moves the barrier 170 upward so that it is disposed in a standby state, as illustrated in FIG. 8.

Next, when the substrate 110 has been loaded into the lower portion of the alignment film etching apparatus 105, the buffer driver 180 moves the barrier 170 downward, i.e., toward the substrate 110, as illustrated in FIG. 9. Either when, or just before the barrier 170 contacts the substrate 110, the buffer driver 180 suspends movement of the barrier 170. This prevents the barrier 170 from generating scratches on the substrate 110.

As the distance between the nozzle 120 and the alignment film 114 increases, the atmospheric pressure plasma P tends to disperse outwardly from the nozzle 120 in all directions. That is to say, a predetermined diameter B of the etched region 116 becomes larger than the diameter A of the nozzle 120. In order for the etched region 116 to have reproducibility, i.e., to have a predetermined diameter, the area in which the atmospheric pressure plasma P is formed between the nozzle 120 and the substrate 110 is preferably surrounded by the barrier 170. Accordingly, the diameter B of the etched region 160 can be controlled so as to be smaller than the diameter D of the barrier 170.

Further, when the atmospheric pressure plasma P is surrounded by the barrier 170, the atmospheric pressure plasma P becomes more concentrated, thereby increasing the etch rate.

As described above, in the exemplary alignment film etching apparatus according to the present invention, since an inorganic alignment film is used, any degradation of the alignment film due to the effects of a backlight unit or other peripherals is prevented. Furthermore, since the alignment film etching apparatus uses an atmospheric pressure plasma without needing a mask, the time required to manufacture LCDs is reduced and the number of devices required to manufacture the LCDs is minimized. In addition, the area in which the atmospheric pressure plasma is formed can be controlled very accurately by forming a barrier between a lower end of the nozzle of the apparatus and the substrate being processed. Additionally, alignment films having sharp sidewall profiles can be patterned by appropriately adjusting the diameter of the nozzle of the alignment film etching apparatus and the distance between the nozzle and the alignment film. Further, alignment films having sharp sidewall profiles can also be patterned by inclining the nozzle of the alignment film etching apparatus to a selected angle relative to the patterned surface of the alignment film.

By now, those of skill in this art will appreciate that many modifications, substitutions and variations can be made in and to the methods for forming LCD alignment films of the present invention and the LCDs manufactured thereby without departing from its spirit and scope. In light of this, the scope of the present invention should not be limited to that of the particular embodiments illustrated and described herein, as they are only exemplary in nature, but instead, should be fully commensurate with that of the claims appended hereafter and their functional equivalents.

What is claimed is:

1. A method for forming an LCD alignment film, the method comprising:
forming a conductive film on a substrate of the LCD;
forming an inorganic alignment film on the conductive film; and,
etching the alignment film using an etching apparatus comprising a nozzle spraying a plasma at atmospheric pressure and without using a mask pattern onto a surface of the alignment film so as to form an etched region in the alignment film that exposes a portion of the conductive film therethrough.

2. The method of claim 1, wherein a diameter of the etched region is about 1-2.5 times a diameter of the nozzle.

3. The method of claim 1, wherein a distance between the nozzle and the inorganic alignment film is about 0.25-0.75 mm.

4. The method of claim 1, wherein the nozzle is inclined at a selected angle with respect to the etched surface of the substrate.

5. The method of claim 4, wherein:
the substrate comprises an active area and a periphery area,
the etched region of the alignment film is positioned between the active area and the periphery area, and
the nozzle is positioned above the etched region and inclined at the selected angle with respect to the surface of the substrate and pointing toward the periphery area.

6. The method of claim 4, wherein the nozzle is inclined at an angle of about 1-45 degrees with respect to the surface of the substrate.

7. The method of claim 4, wherein a distance between the center of a lower end of the nozzle and the inorganic alignment film is about 5 mm or less.

8. The method of claim 1, wherein the inorganic alignment film comprises silicon.

9. The method of claim 8, wherein the inorganic alignment film comprises amorphous hydrogenated silicon, silicon carbide (SiC), silicon oxide (SiOx), or silicon nitride (Si3N4).

10. The method of claim 1, wherein a reaction gas for the atmospheric pressure plasma is SF₆.

11. The method of claim 10, wherein the reaction gas comprises a mixture of N₂ and SF₆.

12. The method of claim 11, wherein the reaction gas comprises a mixture of gaseous N₂ and SF₆ in a ratio of from about 5:1 to about 50:1.

13. The method of claim 1, wherein the substrate is a color filter substrate, and the conductive film exposed through the etched region is a common electrode.

14. The method of claim 1, wherein the substrate is a thin film transistor substrate, and the conductive film exposed through the etched region is a common voltage terminal, an end of a gate line, or an end of a data line.

15. The method of claim 14, wherein the substrate is a thin film transistor (TFT) substrate and the conductive film exposed through the etched region is a common voltage terminal, and further comprising forming a transfer electrode on the portion of the conductive film exposed through the etched region of the alignment film.

16. The method of claim 15, further comprising electrically connecting the transfer electrode to a common electrode of a color filter substrate.

17. An LCD manufactured in accordance with the method of claim 1.

18. A liquid crystal display (LCD), comprising:
a substrate comprising an active area and a periphery area;
a conductive film disposed on the substrate; and,
an inorganic alignment film disposed on the conductive film, the alignment film having an etched region positioned between the active area and the periphery area and through which the conductive film is exposed,
wherein a sidewall profile of the inorganic alignment film in the active area adjacent to the etched region is sharper than the sidewall profile of the inorganic alignment film in the periphery area adjacent to the etched region.

19. The LCD of claim 18, wherein the inorganic alignment film comprises silicon.

20. The LCD of claim 19, wherein the inorganic alignment film comprises amorphous hydrogenated silicon, silicon carbide (SiC), silicon oxide (SiOx), or silicon nitride (Si₃N₄).

21. The LCD of claim 18, wherein the substrate is a color filter substrate and the conductive film exposed through the etched region is a common electrode.

22. The LCD of claim 18, wherein the substrate is a thin film transistor (TFT) substrate, and the conductive film exposed through the etched region is a common voltage terminal, an end of a gate line, or an end of a data line.

23. An alignment layer etching apparatus, comprising:
a power electrode to which a high voltage is applied;
a ground electrode;
a nozzle interposed between the power electrode and the ground electrode and operable to generate an atmospheric pressure plasma for etching an LCD alignment film disposed on a substrate; and,
a barrier formed at an end of the nozzle to surround the atmospheric pressure plasma and thereby prevent it from dispersing outwardly in all directions.

24. The alignment layer etching apparatus of claim 23, wherein the barrier is formed in the shape of an annulus.

25. The alignment layer etching apparatus of claim 23, wherein an inner diameter of the barrier is greater than an inner diameter of the nozzle.

26. The alignment layer etching apparatus of claim 23, wherein the barrier is made of a non-metallic material.

27. The alignment layer etching apparatus of claim 26, wherein the barrier is made of a polymeric material.

28. The alignment layer etching apparatus of claim 27, wherein the barrier is made of PTFE (Polytetrafluoroethylene) or PEEK (Polyether ether ketone).

29. The alignment layer etching apparatus of claim 23, further comprising a buffer driver coupling the barrier to a lower end of the nozzle and operable to move the barrier relative to the nozzle in a length direction of the nozzle.

30. The alignment layer etching apparatus of claim 23, wherein a diameter of an etched region of the alignment layer etched by the atmospheric pressure plasma is smaller than a diameter of the barrier.

31. The alignment layer etching apparatus of claim 23, wherein the alignment film is made of an inorganic alignment film material including silicon.

32. The alignment layer etching apparatus of claim 31, wherein the inorganic alignment film comprises amorphous hydrogenated silicon, silicon carbide (SiC), silicon oxide (SiOx), or silicon nitride (Si₃N₄).

33. The alignment layer etching apparatus of claim 23, wherein the atmospheric pressure plasma is formed by a reaction gas including SF₆.

34. The alignment layer etching apparatus method of claim 33, wherein the reaction gas comprises a mixture of N₂ and SF₆.

35. The alignment layer etching apparatus of claim 34, wherein the reaction gas comprises a mixture of gaseous N₂ and SF₆ in a ratio of from about 5:1 to about 50:1.
